(19) United States
(12) Patent Application Publication
(10) Pub. No.: US 2007/0052484 A1
(43) Pub. Date: Mar. 8, 2007

(54) Self oscillation system capable of eliminating interference

(75) Inventors: Ming-Hsiung Chen, Taipei City (TW); Shang-Shu Chung, Taipei County (TW); Ming-Chung Li, Taipei City (TW)

Correspondence Address: BIRCH STEWART KOLASCH & BIRCH, PO BOX 747, FALLS CHURCH, VA, 22040-0747, US

(73) Assignee: Princeton Technology Corporation

(21) Appl. No.: 11/513,199

(22) Filed: Aug. 31, 2006

(30) Foreign Application Priority Data
Sep. 2, 2005 (TW) 094215103

(51) Int. Cl. H03L 7/00

(52) U.S. Cl. 331/2

(57) ABSTRACT

A self oscillation system capable of eliminating interference is provided. The self oscillation system comprises a plurality of channel oscillation circuits and a plurality of eliminators. The plurality of channel oscillation circuits generates a plurality of channel oscillation signals according to a plurality of channel input signals. The plurality of eliminators respectively coupled to two of the plurality of channel oscillation circuits eliminates cross talk.

### BACKGROUND OF THE INVENTION

1. Field of the Invention

The invention relates to a self oscillation system, and in particular to a self oscillation system capable of eliminating interference.

2. Description of the Related Art

A self oscillation system is a common electronic product that generates oscillation signals with the same frequency for different channels. In practice, the frequency of different channels, however, is not the same due to inaccurate element values. Frequency differences cause cross talk between channels and generate an interference signal. Therefore, when the self oscillation system used in a Class-D amplifier, the interference signal generates a noise that may be distressing to a user.

### BRIEF SUMMARY OF THE INVENTION

A detailed description is given in the following embodiments with reference to the accompanying drawings.

A self oscillation system capable of eliminating interference is provided. The self oscillation system comprises a plurality of channel oscillation circuits and a plurality of eliminators. The plurality of channel oscillation circuits generates a plurality of channel oscillation signals according to a plurality of channel input signals. The plurality of eliminators respectively coupled to two of the plurality of channel oscillation circuits

### BRIEF DESCRIPTION OF THE DRAWINGS

The invention can be more fully understood by reading the subsequent detailed description and examples with references made to the accompanying drawings, wherein:

FIG. 1 is a block diagram of a self oscillation system capable of eliminating interference according to an embodiment of the invention;

FIG. 2 is a block diagram of the self oscillator in FIG. 1;

FIG. 3 is a block diagram of the eliminator in FIG. 1.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

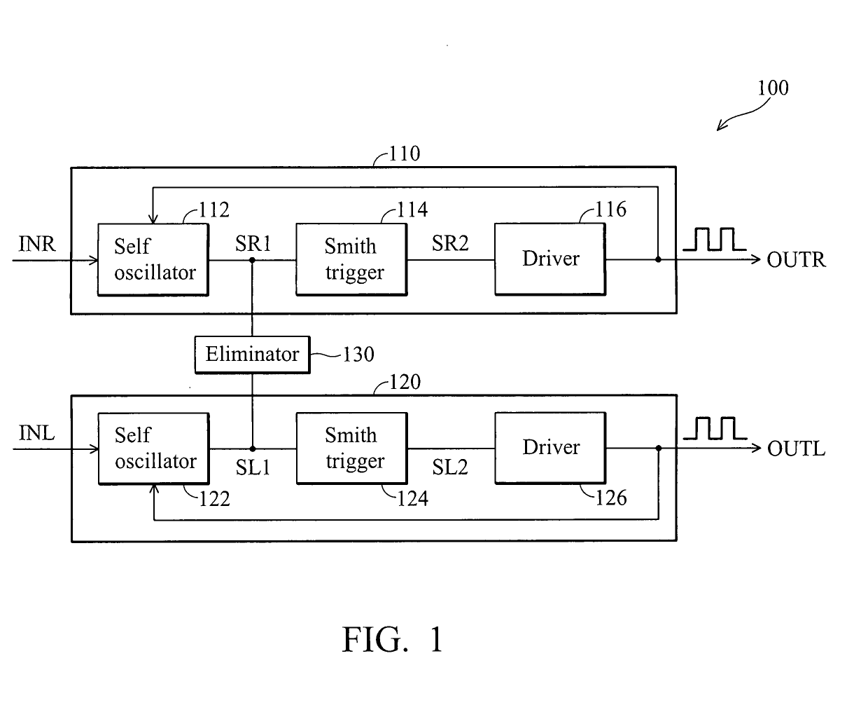

Please refer to FIG. 1. FIG. 1 is a block diagram of an embodiment of a self oscillation system 100 capable of eliminating interference. The self oscillation system 100 comprises a plurality of channel oscillation circuits 110 and 120, and an eliminator 130. The channel oscillation circuits 110 and 120 generate the right-channel oscillation signal OUTR and the left-channel oscillation signal OUTL according to the right-channel input signal INR and the left-channel input signal INL, respectively. The eliminator 130 eliminates the cross talk between the channel oscillation signals OUTL and OUTR. Please note that the number of channel oscillation circuit equal to two in the embodiment, is given as an example, not a limitation. In other words, multiple channels can also be applied. Taking the channel oscillation circuit 110 as an example, a detailed description of the channel oscillation circuit is provided in the following.

The channel oscillation circuit 110 comprises a self oscillator 112, a Schmitt trigger 114, and a driver 116. The self oscillator 112 generates an oscillation signal SR1 according to the right-channel input signal INR. The Schmitt trigger 114 generates another oscillation signal SR2 according to the oscillation signal SR1. The driver 116 drives the signal SR2 to generate the channel oscillation signal OUTR corresponding to the right channel. A detailed description of the driver is omitted for the sake of brevity since it is well known to those skilled in the art. A detailed description of the self oscillator 112 and the Schmitt trigger 114 is provided in the following.

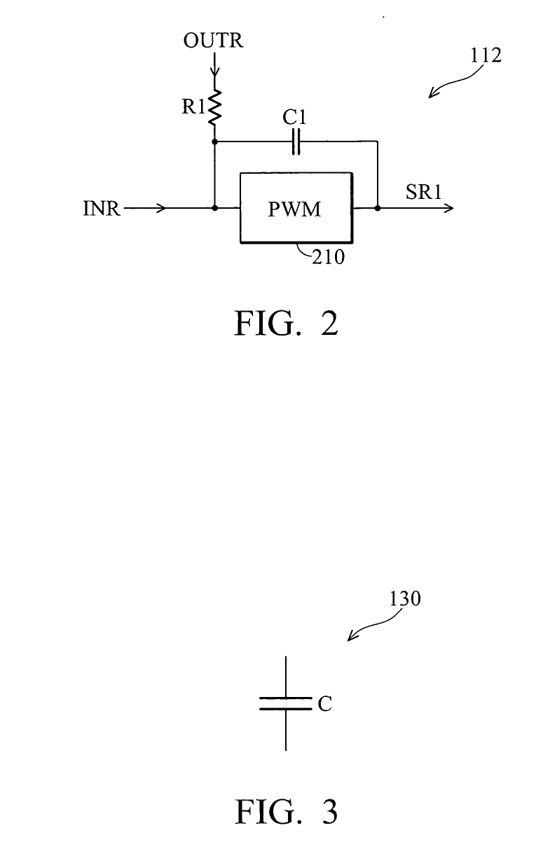

Please refer to FIG. 1 and FIG. 2 at the same time. FIG. 2 is a block diagram of the self oscillator 112 in FIG. 1. The self oscillator 112 comprises a pulse width modulator (PWM) 210, a resistor R1, and a capacitor C1. A detailed description of the PWM 210 is omitted for the sake of brevity since it is well known to those skilled in the art. The channel oscillation signal OUTR charges and discharges the capacitor C1 through the resistor R1 to generate the oscillation signal SR1. The retardation level of the oscillation signal SR2 and the charging/discharging current determines the oscillation frequency of the channel oscillation signal OUTR. Ideally, the oscillation frequency of the channel oscillation signal OUTR generated from the channel oscillation circuit 110 is the same as the oscillation frequency of the channel oscillation signal OUTL generated from the channel oscillation circuit 120. In practice, due to the inaccurate element value, the oscillation frequency of the channel oscillation signal OUTR is not the same as the oscillation frequency of the channel oscillation signal OUTL. The eliminator 130 is thus utilized to eliminate cross talk between the channel oscillation signals OUTL and OUTR and generate the same oscillation frequency of the channel oscillation signals OUTL and OUTR. A detailed description of the eliminator 130 is provided in the following.

Please refer to FIG. 3. FIG. 3 is a block diagram of the eliminator 130 in FIG. 1. When the voltage level of the channel oscillation signal OUTR from the driver 116 is high, the voltage level of the oscillation signal SR1 decreases until reaching a voltage transition point. When the voltage level of the channel oscillation signal OUTR from the driver 116 is low, the voltage level of the oscillation signal SR1 is increased. For example, if the frequency of the channel oscillation signal OUTR is higher than that of the channel oscillation signal OUTL, the oscillation signal SR1 is charged/discharged through the eliminator 130 to increase the frequency of the oscillation signal SL1. Hence the frequency of the channel oscillation signals OUTL and OUTR is always the same.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A self oscillation system capable of eliminating interference, comprising:
a plurality of channel oscillation circuits for generating a plurality of channel oscillation signals according to a plurality of channel input signals; and
a plurality of eliminators respectively coupled to two of the plurality of channel oscillation circuits for eliminating cross talk.

2. The self oscillation system as claimed in claim 1, wherein a channel oscillation circuit corresponding to a specific channel comprising:
a self oscillator for generating a first oscillation signal according to a channel input signal;
a Schmitt trigger coupled to the self oscillator for generating a second oscillation signal according to the first oscillation signal; and
a driver coupled to the Schmitt trigger for driving the second oscillation signal to generate a channel oscillation signal corresponding to the specific channel.

3. The self oscillation system as claimed in claim 1, wherein the eliminator is a capacitor.

4. The self oscillation system as claimed in claim 1, wherein the plurality of channel oscillation circuits comprises:
a first channel oscillation circuit for generating a first channel oscillation signal according to a first channel input signal;
a second channel oscillation circuit for generating a second channel oscillation signal according to a second channel input signal; and
an eliminator coupled to the first and the second channel oscillation circuits for eliminating a cross talk between the first and the second channel oscillation signals.
